(19) United States
(12) Patent Application Publication
(10) Pub. No.: US 2005/0051208 A1
(43) Pub. Date: Mar. 10, 2005

(54) System for transferring heat in a thermoelectric generator system

(76) Inventor: Robert L. Mount, Lindon, UT (US)

Correspondence Address: Everett D. Robinson;Parsons Behle & Latimer, 201 South Main Street, Suite 1800, P.O. Box 45898, Salt Lake City, UT, 84145-0898, US

(21) Appl. No.: 10/871,544

(22) Filed: Jun. 17, 2004

Related U.S. Application Data
(60) Provisional application No. 60/479,248, filed on Jun. 17, 2003.

(51) Int. Cl. H01L 31/00; F24J 2/34

(52) U.S. Cl. 136/259

(57) ABSTRACT

Disclosed herein are thermoelectric generator systems dissipating into a foundational element. Detailed information on various example embodiments of the inventions are provided in the Detailed Description below, and the inventions are defined by the appended claims.

### CROSS REFERENCE TO RELATED APPLICATIONS

This Application claims the benefit of the U.S. Provisional Application No. 60/479,248 filed Jun. 17, 2003, which is hereby incorporated by reference in its entirety.

### BACKGROUND

The claimed inventions relate generally to thermo-electric generators and solar radiation collectors, and more particularly to thermoelectric generator systems dissipating heat into a building foundation.

### BRIEF SUMMARY

Disclosed herein are thermo-electric generator systems dissipating into a foundational element. Detailed information on various example embodiments of the inventions are provided in the Detailed Description below, and the inventions are defined by the appended claims.

### BRIEF DESCRIPTION OF THE DRAWINGS

FIG. 1A shows an exemplary thermo-electric power generator including a solar concentrator.

FIG. 1B shows in detail the thermal transfer junction of that generator.

FIG. 1C depicts the transfer of heat through that thermal transfer junction.

FIG. 2 illustrates a power-generating array including a group of solar generators.

FIG. 3A depicts a thermal transfer system including a solar generator array and a dissipation conduit embedded in a building foundation.

FIG. 3B shows a thermal transfer system including a solar generator array and a dissipation tank.

FIG. 4 shows a thermal transfer system including a solar generator array and a dissipation conduit embedded in a partially buried concrete wall.

FIG. 5 depicts the conversion of incoming solar radiation to heat in a solar thermoelectric system.

FIGS. 6A and 6B show results of simulation of a model thermal transfer system including a solar thermoelectric generator.

Reference will now be made in detail to thermo-electric generator systems dissipating into a foundational element which may include some more specific embodiments of the claimed inventions, examples of which are illustrated in the accompanying drawings.

### DETAILED DESCRIPTION

With ever increasing dependence on fossil fuels, interest in renewable energy generation is increasing. Renewable energy sources are mostly associated with the sun, the exception being geo-thermal energy extracted from heat sources deep within the earth (for those fortune enough to have access to this energy source). These energy sources are highly desirable in that they can be captured at a low long-term cost to the environment—i.e. they can be utilized without polluting the air, water and ground and do not add greenhouse gasses to the atmosphere. Electricity is the energy form of greatest interest, as it is transportable across significant distances, with heat being a secondary form useful for a few specialized local uses. Presently the technologies for generating electricity from renewable sources that are paid the most attention to are (1) solar cells, (2) wind turbines, (3) hydroelectric turbines and perhaps (4) bio-mass burning power plants.

Solar cell technology is gaining in popularity, with many homeowners taking advantage of government incentives to offset a steep initial cost of installation. Solar cells, or photo-voltaics, produce direct current, and thus most installations utilize an inverter to power household appliances and alternatively to sell power to the utility grid. Batteries are sometimes included in solar cell systems to provide power at times when sufficient solar radiation is not received, especially for systems that are not grid-tied. Solar cells, however, are inefficient converters of energy, only converting approximately 15 percent of the solar radiation falling on the cells to usable electricity. Even so, many locations may be powered with solar cells if they cover a large area of the roof and care is taken by the homeowner to select energy-conserving appliances and fixtures.

Many wind turbines have been built in recent years, and have provided some supplement to the generally available electricity. Very large wind turbines (over 100 ft. high) are the focus of most present construction, with smaller turbines being available that may generate a fraction of a household's energy needs. Wind turbines are not generally suitable for use in residential neighborhoods, as they must usually be positioned higher off the ground than many ordinances would allow. Additionally, homes are generally preferred to be built in calm areas, and thus the windy ridge tops are only the homes of a minority. Furthermore, wind turbines are at the mercy of the weather, and may leave a consumer without power generation for days in calm weather. Wind turbines may, however, provide an important power source to farms and other rural locations.

Common hydroelectric power generators utilize the motion of water to drive a turbine to generate electricity. Hydroelectric power is a suitable choice where a large body of water is available at a substantial altitude drop, or for a river or tidal body, sufficient water velocity. Hydroelectric generators on a scale suitable for a household or farm are uncommon, as a large pond is required to provide sufficient energy storage capacity. Hydroelectric power systems for supplying a house, business or farm are therefore not practical in many if not most circumstances.

Biomass electric generators utilize waste biological products, such as agricultural and forestry wastes and, to some extent, household garbage as fuel. More recent generators capture gasses (methane) from decomposing biomass material, which greatly reduces the harmful emissions of combustion. Older generators might, for example, burn solids heating a boiler and rotating a turbine generator. Biomass generators may provide a power source free from interruption, as the supply of combustible material is usually constant and easily regulated to meet any present demand. Common sites of biomass generators are landfills and large farms, which have large and continuing supplies of waste biological products. Biomass generators are usually not a good match to smaller entities, such as businesses and households, which do not have a sufficient stream of fuel to meet their energy needs.

Thermoelectric devices, devices which convert heat to electricity, have been known for some time, but have not attained popularity due to the immaturity of the technology. Early thermoelectric junctions were fashioned from two different metals or alloys, and were capable of producing a small current at a small voltage. Speaking in simplistic terms, as heat is carried across the junction a differential voltage is created, by which a portion of the heat may be converted to electricity. It was later realized that several junctions can be connected in series to provide greater voltages, connected in parallel to provide increased current, or both. With the emergence of the semiconductor industry have come thermoelectric devices constructed of doped semiconductor materials. Modern thermoelectric generators (TEGs) can include many junctions in series, which results in higher and more usable voltages, and can be manufactured in modular forms to provide for parallel connectivity to increase generated current.

Thermoelectric generator efficiency is generally dictated by two factors: the Carnot efficiency and the TEG efficiency. These two efficiencies are given below.

$$\begin{matrix}{η}_{TEG} = \frac{\sqrt{1 + ZT} - 1}{\sqrt{1 + ZT} + \frac{{T}_{c}}{{T}_{h}}} \\ {η}_{Carnot} = 1 - \frac{{T}_{c}}{{T}_{h}}\end{matrix}$$

In the above equations Tₕ and T_{c} are respectively the hot and cold sides of the TEG in Kelvin, and ZT is a parameter called the figure of merit. The total efficiency is the product of these two efficiencies:
η_{Total}=η_{TEG}×η_{Carnot}

The total efficiency is therefore a function of the figure of merit, ZT, the hot temperature, Tₕ, and the cold temperature, T_{c}. The figure of merit, ZT, depends upon the the properties of the semiconductor, the absolute temperature at which the TEG is operating, and the temperature difference across the TEG, Tₕ-T_{c}. The first term, Z, in the figure of merit depends upon the thermal conductivity and the electrical resistivity of the material, and, for some TEGs, the Seebeck coefficient. The second term in the figure of merit, T, is the absolute temperature at which the TEG operates. Equations for both of these terms are:

$$\begin{matrix}Z = \frac{{α}^{2}}{k ρ} \\ T = \frac{{T}_{h} + {T}_{c}}{2}\end{matrix}$$

where, α is the Seebeck coefficient, k is thermal conductivity, and ρ is the electrical resistivity.

Previously, a TEG with a ZT of around two was the best available. Today, thermoelectric generators with a ZT of three to four are being developed. Despite this improvement, the total efficiency is still limited by the Carnot efficiency, which is strictly a function of the hot and cold temperatures. Thus for a finite temperature difference, it is impossible to obtain an efficiency higher than the Carnot efficiency, regardless of ZT. The reader will therefore see that a large Tₕ and a relatively small Tₕ will result in more efficient energy conversion.

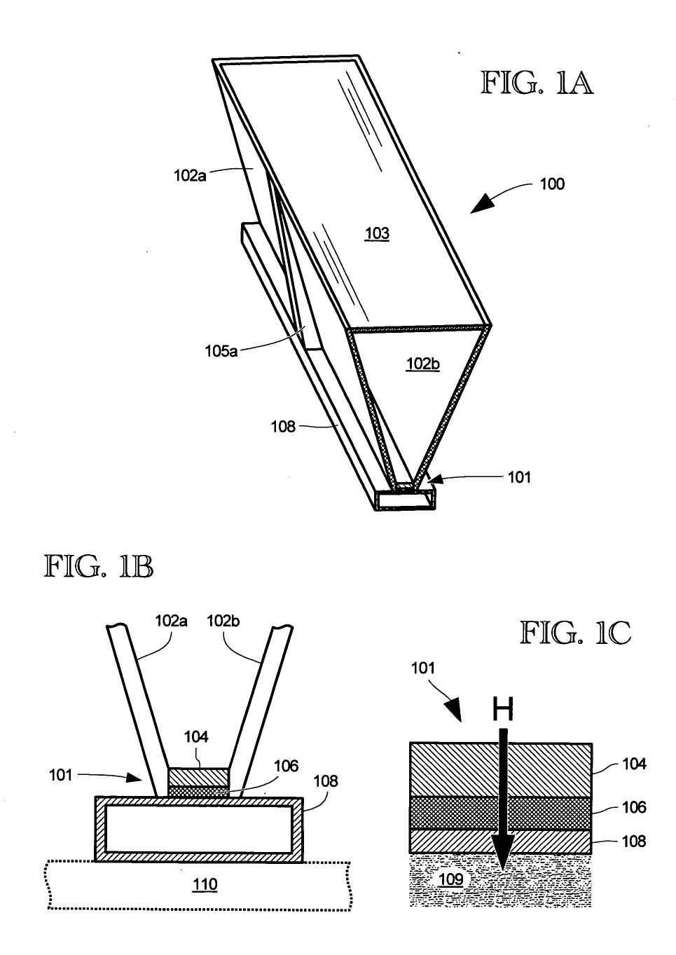

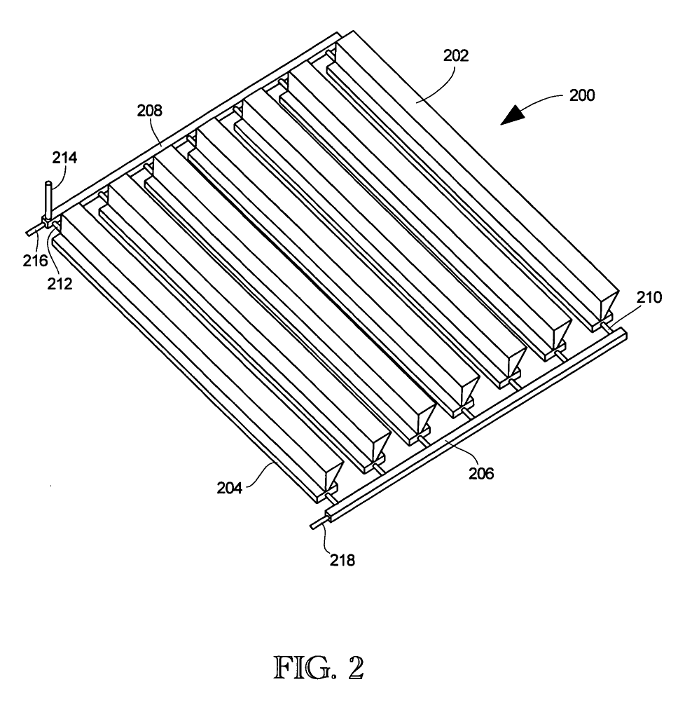

The efficiency of solar power generators may be increased, therefore, through the use of solar concentrators. Referring now to FIGS. 1A, 1B and 1C, an exemplary power generator 100 is depicted including a solar concentrator. Generator 100 includes a fresnel lens 103 which focuses light and infrared radiation from the sun onto a solar radiation collector, which in this example is a collector plate 104. Lens 103 is supported above by structures 102a and 102b, which in this example are simple walls. Structures 102a and 102b are fastened to channel 108 through brackets, one of which is shown as 105a A thermo-electric generator (TEG) 106 is sandwiched between plate 104 and channel 108, utilizing a thermal compound to provide a good thermal interface from plate 104 to TEG 106 and from TEG 106 to channel 108. The combination of plate 104, TEG 106 and channel 108 forms a thermal transfer junction 101, which is more closely shown in FIG. 1B. Now it is to be understood that TEG 106 might be an array of smaller TEGs, arranged in a layer and connected as a group to provide a specified voltage and/or current under a given solar exposure.

Channel 108 includes a cavity in which a thermal carrying liquid agent 109 may be contained. Referring now to FIG. 1C, heat is generally transferred in the direction labeled “H”, which is more precisely from plate 104, through TEG 106 and channel wall 108 to cooling liquid 109. Additionally, obstructions may be placed within the cavity, perhaps formed in the channel walls or included in an insert installable to the cavity, thereby creating turbulence in the thermal carrying liquid and providing mixing of the liquids near and away from the region near the TEGs. A system might also provide for cavitation pockets near the TEGs, which may improve thermal transfer to the cooling liquid.

In the above example, the lens 103 is not spherical in nature, but rather cylindrical. Thus parallel light from directly above will be focused in a line running the length of plate 104, rather than at a single point. Lens 103 may be substituted with an ordinary lens made from glass or other material, although a fresnel lens may be expected to reduce the weight and profile of the collector. In an alternate design, structures 102a and 102b form a parabolic mirror focused on a collector which may be higher in profile than plate 104. In that design it may be possible to omit lens 103 entirely, or replace it with a transparent pane. It may also be desirable to provide substantial distance between lens 103 and plate 104 so as to reduce chromatic distortion, by which more of the incoming spectra may be brought to more evenly strike plate 104.

In the above example, structures 102a and 102b are insulative in nature, particularly in the region where these structures abut plate 104. By utilizing insulative materials, more heat may be retained in plate 104 which will result in a general increase of efficiency of the generator. If desired, thermally conductive materials may be substituted in structures 102a and 102b, utilizing an insulating layer at the interface between those structures and plate 104. That layer might be a high-temperature material, such as fiberglass mat. Additionally, structures 102a and 102b may not enclose the airspace above plate 104, but may permit some air to pass through, keeping the interior temperature of the collector to a manageable level. Structures 102a and 102b may be fashioned with a reflective surface toward the inside of the collector, to avoid heat buildup in these structures.

The collecting plate 104 may be fashioned from any heat-resistive material, however certain properties will improve performance of the generator. A thermally conductive material will improve thermal transfer through junction 101 and thereby improve power output. Some of the more common suitable thermally conductive materials include copper, aluminum, gold, glass and ceramic materials, and many other metals and metal alloys. If desired, a material having a relatively high specific heat, such as iron or steel, may be used to increase the time constant of heating and cooling of the plate. Such a plate stores more thermal energy, and therefore may act to smooth out variations in the received radiation, for example when clouds pass between the sun and the generator. If plate 104 is made sufficiently large, enough heat might be stored to supply power for a period of time through extended interruptions of solar radiation.

A material might also be chosen for its machinability and corrosion resistance, for example aluminum or stainless steel. Likewise, a collecting plate might be plated with a corrosion resistive layer, including metals such as zinc, nickel and gold. Resistance to oxidation may be particularly important where the design dictates operation of the generator using high plate temperatures. For high plate temperatures, a material with a high melting point should be used, for example bronze or steel, or more exotic metals such as tantalum or tungsten may be used for extreme temperature operation.

A collecting plate may also be darkened to absorb more radiation, particularly on the light-exposed side. Coatings may be used, keeping in mind the conditions of operation. For low-temperature operations, ordinary lacquers and enamels might be used. For mid-range temperatures, a plate might be coated with a high-temperature enamel. A plate might also include a thin dark coating on the exposed surface, for example graphite particles in a substrate or deposited to pores in the surface of the plate.

Many thermal transmissive compounds might be used to thermally join plate 104, TEG 106 and channel 108. The selection of a compound will depend on the conditions of operation, such as temperature of the plate, the stability of the collector plate, TEG, and channel materials, exposure to the elements, etc. For designs utilizing low temperature operation and protection from the elements, a thermal grease or even ordinary petroleum grease might be used. For high-temperature designs, an epoxy or paste relatively free from volatiles might be better suitable. For designs utilizing materials with different coefficients of expansion, particularly for mismatches between a collector plate and a TEG, a non-hardening compound should be chosen with sufficient elasticity.

Referring now to FIG. 2, a group of solar generators may be combined into a power-generating array 200. In the example of FIG. 2, each solar generator includes a concentrator 202 and a channel 204 for transporting heat transferred across an included TEG, not shown. The array includes an intake manifold 206 and a waste manifold 208, wherein channels are connected through intake tubes 210 and waste tubes 212. An intake fitting 218 and a waste fitting 216 are provided to connect a thermal regulation system whereby the temperature of liquid passing through intake manifold 206, channels 204 and waste manifold 208 may be regulated. The combination of channels 204, tubes 210 and 212, manifolds 206 and 208 and fittings 216 and 218 form one example of a TEG conduit, by which heat (or cold) may be transferred from thermoelectric generators to a thermal carrying liquid agent and transported away. A filler cap incorporating a pressure valve 214 is provided to prevent excessive hydraulic pressure of the contained liquid from damaging the system, which might occur in the event of a blockage or excessive heating of the liquid.

In order to maximize power generation, it may be desirable to orient the solar collectors with the sun to maintain proper focus of concentrators 200. In one alternative, array 200 is mounted above a substantially planar structure, and each of concentrators 200 is fixed to that structure. In that system, the array 200 may be mounted relatively high on a mast, to permit rotation of the entire array through a wide latitudinal (east-west) arc. A tracking device may be incorporated to maintain alignment of the array with the sun, including a suitable motor and alignment mechanism.

As collectors 202 are long in one axis, a misalignment of the sun toward the ends of the collector of a few degrees will not generally affect the power output. It may, therefore, be desirable to position the array such that the collectors are oriented generally in a north-south direction. Doing so may obviate the need to make daily latitudinal adjustments to the array, to correct for solar position throughout the seasons. Alternatively, if collection plates are designed relatively wide in comparison to the area of focus of the collector, a misalignment tolerance of several degrees may also be obtained. Additionally, a fresnel lens may be fashioned in a curved rather than a flat shape, which may present a similar profile to incoming solar radiation through a range of desired orientations. In that kind of system, it may be acceptable to orient the collectors in an east-west direction to avoid daily adjustment.

In another alternative, the solar generators are rotatably mounted to manifolds 206 and 208, which may rotate generally about the axis of intake tubes 210 and waste tubes 212. A suitable mechanism would attach to channels 204 to control the position of the generators either individually or in common. Each of tubes 210 and 212 might be fashioned from rigid pipe, including a rotatable slip joint Alternatively, tubes 210 and 212 might be fashioned from flexible pipe, if the maximum coolant temperature is sufficiently low, each tube including a length permitting movement throughout the range of rotation.

As to the construction of the conduits of array 200, any number of constructions might be effectively used. In one example, each of channels 204 and manifolds 206 and 208 are fashioned from extruded aluminum in a generally rectangular shape, using sealing encaps. Where connections are to be made, a threaded hole may fashioned to accept a threaded pipe or pipe fitting.

In designs utilizing water as the thermal carrying agent, ordinary plumbing materials and techniques may be used. In an alternative construction, manifolds 206 and 208 are constructed of rigid pipe utilizing standard elbows, tees and fittings, of any of copper, galvanized, PVC or ABS pipe. In yet another construction, manifolds 206 and 208 may be constructed of flexible pipe utilizing push-in fittings and secured to a stable base.

If a low temperature is maintained within the thermal transfer agent, plastic plumbing materials may be utilized. As an array will be placed in the open, it may be considered to be accessibly maintainable. If that is the case, low cost vinyl tubing might be an acceptable alternative, although UV protection may be desirable to avoid premature failure.

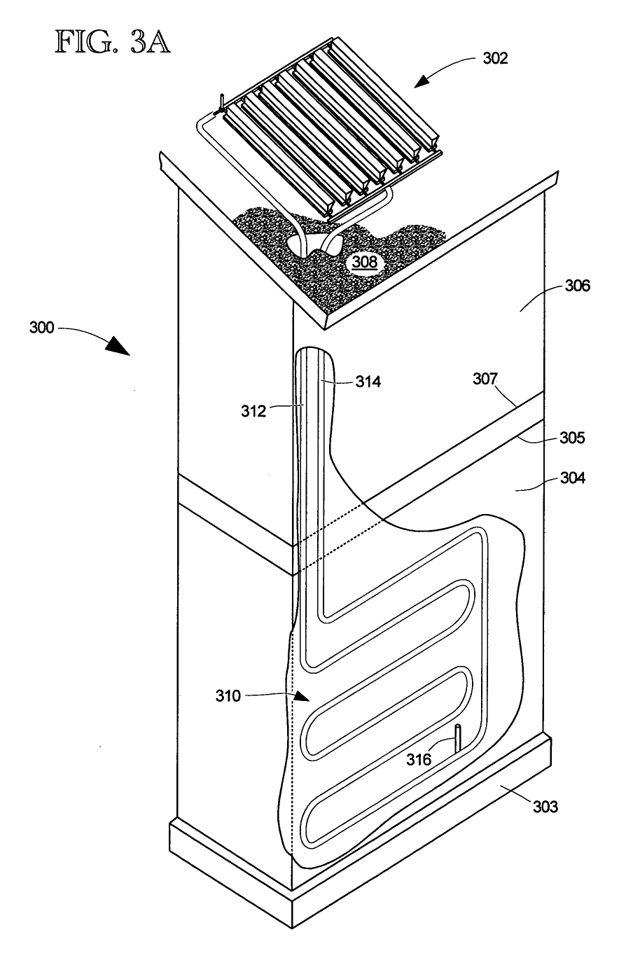

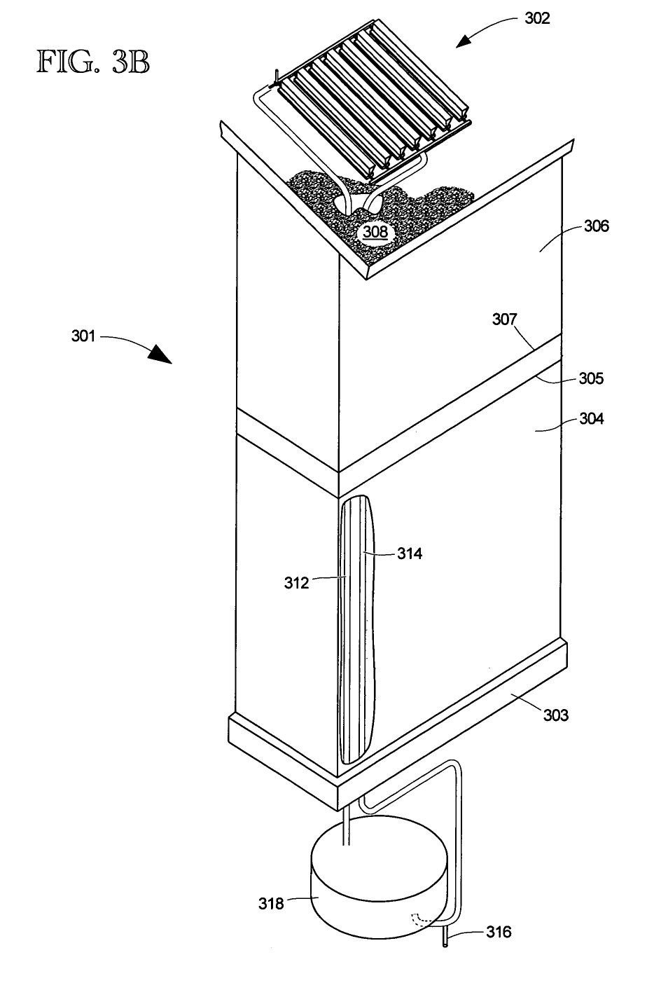

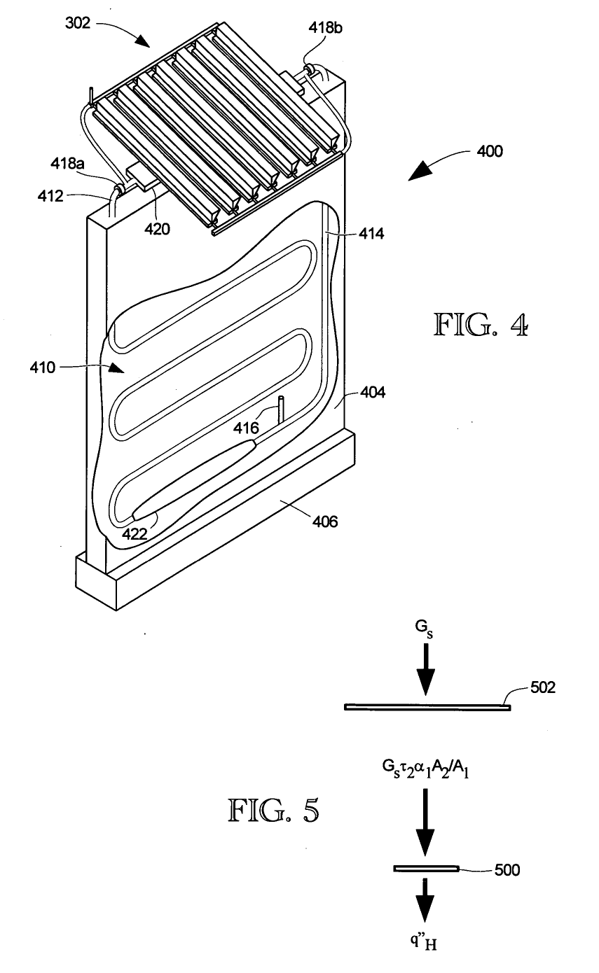

FIG. 3A shows a thermal transfer system 300 including a solar generator array 302 similar to that appearing in FIG. 2. Array 302 is mounted on or above a building composed of a roof 308, a foundation 304 resting on a footing 303, and a structure 306. In the example of FIG. 3A line 305 represents the level of ground resting against the foundation, and line 307 is the interface between the foundation 304 and the building structure 306, which is representative of a building having a basement. A dissipation conduit 310 is provided to transfer heat to the thermal mass provided by foundation 304. An intake conduit 314 and a waste conduit 312 connect to the TEG conduit of array 302 and dissipation conduit 310 forming a transfer circuit whereby a thermal agent may be circulated throughout the system 300. A pump 316 is provided to motivate the thermal carrying agent through the transfer circuit, in this example located at or near the lowest point in the circuit. Access to pump 316 may be through an access hole in foundation 304, by which pump 316 may be maintained or replaced. The motor for pump 316 might be located elsewhere if provision is made to transfer force to the pump, for example through a rotating shaft or compressed air line. The form of structure 306 is not particularly important, so long as connection conduits 312 and 314 are provided passage from the array 302 to the dissipation conduit 310.

Foundation 304 provides a thermal mass whereby thermal energy may be deposited from the thermal liquid in the dissipation conduit 310. The area where this thermal transfer takes place will be referred to as a foundation portion. Dissipation conduit 310 is fashioned to include a length of conduit sufficient to dissipate the heat generated by the solar array 302 into the thermal mass of the foundation 304 maintaining a temperature of the thermal agent being pumped through the system. In this example, conduit 310 is fashioned from several loops, although other paths might be chosen according available space and properties of the foundation material. In cold climates, it may also be desirable to maintain the majority of the conduit embedded in the foundation below the frost line to avoid freezing, particularly if thermal agents with relatively high freezing points, such as water based agents, are used. If agents other than water are used, a “freezing line” may be determined at a depth in the soil that maintains a temperature above the freezing point of the agent throughout winter seasons.

In inferior systems, waste heat transferred through a TEG is transferred to the air, in some cases through a vaned heat sink. In some cases, the designer has given little thought as to where to deposit this waste heat. The failure to provide a sufficient heat sink may result in the cool side of the TEG getting hot, which reduces the temperature differential across the hot and cold sides, further resulting in decreased electric production. Air has been a popular heat sink, as it is plentiful wherever sunlight may be received and transportable, through the use of fans or convection. Air, however, has a low thermal density and conductivity. To overcome this, several steps may be taken. First, the sink may be maintained at a high temperature relative to the air. This is undesirable, as if the sink is kept hot, the temperature differential across the TEG is reduced, which decreases the efficiency of the generator. Second, large heat sinks may be used. This may also be undesirable, as the profile of the generator system is increased, especially near the TEGs. Third, the air velocity across the sinks may be increased. This may provide a modest improvement at the expense of increased energy consumed by the generator system. Additionally, increasing the velocity of the air across the sink can only bring the temperature closer to the ambient air temperature, and thus the rule of diminishing returns quickly takes hold.

It may be desirable to take advantage of heat sinks in the vicinity of the point of electric generation. The modern trend is to produce the electricity for a single household or business locally, if utility power is deemed undesirable or unavailable. As photovoltaics are almost universally looked to to provide locally produced electricity, little thought has been expended to find ways of improving thermoelectric generation by improving the thermal dissipation of a system in the vicinity of a home or business.

A local source of water, such as a well, might be considered as a heat sink. Many, however, may not have this as a practical option either because they do not have access to a well or because the only water available is expensive culinary water. Additionally, many areas have a shortage of water and can little afford the additional water consumption.

In some home heating/cooling systems, heat pumps are connected to fluid circuits passing through the soil. These systems may provide a modest degree of heating or cooling through a transfer unit that transfers the ambient soil heat to the air in a building. Most soils, however, have a significant amount of air between the soil particles, which makes the soil a poor conductor of heat. Heat pump systems therefore require a large loop of conduit, perhaps hundreds of feet, to provide adequate performance. Additionally, a large portion of the earth is required to be excavated and refilled for the sole purpose of placement of the conduit

Ordinary concrete is a material having relatively good thermal mass and transfer characteristics. The water and aggregate stone in concrete mainly support these properties. Additionally, concrete is utilized in most modern building construction in foundations and slabs supporting the building structure. In the example of FIG. 3A, foundation 304 is constructed of ordinary concrete. The surface of the foundation portion contacting the soil is relatively large, which assists in transferring heat into the nearby soil. By utilizing the concrete as a heat-transferring member, a reduction in the size of a cooling conduit may be achieved.

Air entrained concrete is sometimes used in construction, particularly where the concrete may be exposed to freeze/thaw cycles. Air entrained in concrete will tend to decrease both the thermal mass and transfer ability of concrete, which should be taken into consideration when designing a thermal transfer system. If desired, the foundation portion might be poured using ordinary concrete while the remainder of the foundation is poured using an admixture. In that case, the foundation portion may be located below the frost line. In another alternative, the foundation portion might be a separate concrete slab or block from the building foundation, buried outside the building below the frost line.

In another example, the foundation portion (or the entire foundation) may be coated with a sealant to maintain a high moisture level in the concrete, especially in dry climates. If this is done about the time of the pour, the concrete will tend to cure harder as an additional benefit.

Other materials other than concrete may be used, keeping in mind that changes to the effective thermal mass and transmissivity will affect the required surface area of the portion of the foundation including the dissipation conduit. Concrete block might be used, for example, provided that the hollow spaces surrounding the dissipation conduit are filled with mortar, cement or other solid material. Loose fill material, such as sand, might also be used, however the conduit length and foundation portion may need to be increased to support the desired thermal transfer.

For any foundation portion, consideration should be taken as to the final strength, as some strength may be lost due to the inclusion of the conduit. It may, therefore, be desirable to thicken or reinforce the foundation portion to provide strength.

A system similar to that shown in FIG. 3A is shown in FIG. 3B, but in system 301 the dissipation conduit is replaced by a tank 318. Cooling of the thermal agent takes place, in this example, through the walls of tank 318. The size of tank 318 should therefore be chosen to have a surface area large enough to conduct heat from the liquid in the tank to the surrounding matter. Tank 318 is shown located buried under the foundation footing level, although it might be located elsewhere and at higher levels if desired, provided that the tank remains in substantial contact with the earth or other heat sink.

Depicted in FIG. 4 is an alternate stand-alone solar generator and transfer system. In this example, a solar generator array 302 is rotatably fastened to a mount 420, the rotation provided by couplers 418a and 418b. In this example, the thermal mass is provided by a concrete wall 404 resting on a footing 406, rather than a building foundation. The wall 404 may be entirely surrounded by earth or other material. A thermal agent is circulated by pump 416 up intake conduit 414, through the manifolds and conduits of array 302, returning down waste conduit 412 to the dissipation conduit 410. An expansion bladder 422 provides for expansion of the thermal agent should a temperature rise cause expansion.

In the above disclosed examples, a foundation portion might be a portion of a foundation wall. Departing slightly from the above disclosed examples, a foundation portion might also be a portion of a foundation footing or slab. If a slab is used as a thermal mass, some advantage may be had to provide heat to a lower space through radiation from the floor, which might be useful in northern locations. A foundation portion likewise might be any mass of foundation material located proximally to a solar collector or collector array.

The selection of tubing throughout the system again will depend on the environment of use. For tubing in a dissipation conduit, a tubing should be selected that will withstand the pressures and temperatures of construction, as well as the maximal temperatures that might be sustained in the thermal carrying agent. Rigid pipe formed of copper, galvanized steel or copper may be used in a wide variety of installations, due to the relative strength and stiffness of the pipe as well as the relatively high thermal conductivity and resistance to high temperatures. Plastic rigid pipe may also be used, for example PVC or ABS irrigation pipe, provided that sufficient lengths are used to overcome the insulative nature of the plastic material and low temperatures are maintained in the thermal carrying agent. Flexible pipe may also be used, however thin-walled types may collapse under the weight of wet cement during construction, particularly if the pipe is embedded deep down a foundation portion. Care should therefore be used with flexible pipe to ensure it is not positioned too deeply. PEX type plastic pipe might be advantageously used to form the conduit, as it is relatively easy to bend and position and is designed for long life. Alternatively, other plastic pipes might be used, such as vinyl tubing, and because exposure to heat, light and other degrading elements might be expected to have a significantly longer than usual service life. Pipes including small turbulence-generating obstructions or a roughened inner wall may provide better thermal transfer efficiency in a dissipation or cooling portion. Other interconnection pipes might be fashioned using ordinary construction and plumbing methods and materials, joined to the other conduit by appropriate fittings.

A system might also be designed to maintain the temperature of the thermal carrying agent at levels where persons coming into accidental contact would not suffer burns or serious injury. In one example, the temperature is maintained at below 120 degrees fahrenheit under conditions of sustained fill solar exposure. Other systems might be designed to allow heat to build up in the thermal mass of the foundation and/or thermal agent during the interval of daily solar exposure, released at night through the surrounding soil. In that system the dissipation conduit or the foundation portion might be smaller, taking advantage of the intervals of solar exposure and darkness.

As for construction of a foundation portion, a framework to support the dissipation conduit before and during a concrete pour and during curing may be useful to maintain proper conduit position, particularly if the conduit is formed of a relatively flexible material. In many if not most cases, a network of reinforcement steel bar or mesh will be embedded into a foundation. The conduit might be conveniently supported on that structure, although for strength the conduit should probably be separated from reinforcement elements by a small distance. An additional network may be added if necessary, providing support for the conduit, which might be constructed of steel, wire, or other stiff material. Alternatively, the conduit might be hung from wires fastened to a support above the foundation portion to be poured, which can be trimmed flush with the final block after curing. For rigid pipe, such as galvanized steel and thick copper pipe, it may not be necessary to fasten the pipe to a support structure if the pipe is supported from above.

It may also be desirable to provide a cutout mechanism to the solar collector to reduce the solar input to a collector, to prevent over-temperature conditions. That mechanism might take the form of louvers or shades mounted over the solar collectors, and might be configured to be closed in the absence of control and open through a motor or solenoid. In an alternate mechanism, a solar collector might be pointed away from the sun in over-temperature conditions. The mechanisms might be configured to sense the temperature at a collection plate, the thermal carrying liquid nearby, or both. The mechanism might also have several graduated positions by which the solar input to the collector might be finely controlled, which may help to keep a generator more closely to its maximal output capacity.

For each of the above examples, the solar collector might be replaced by a thermal radiator. In those examples, heat is supplied to the thermal agent from the foundation material or surrounding soil. The heated agent is pumped to the TEG where it is conducted through and radiated away, producing electricity. It should therefore be recognized that the thermal transfer systems herein depicted and described are reversible, and may be connected to TEG facilities for collecting, conducting or radiating heat in order to generate electricity.

Additionally in the above examples, a thermoelectric generator might be designed to operate utilizing the Seebeck effect, or might utilize another thermoelectric principle of operation. For example, the thermoelectric generators in the above described systems might be thermionic generators, if high plate temperatures are utilized to drive operation into that phase. Thus the TEGs referenced above might be any device capable of generating electricity from thermal conduction, and are not restrictive to any particular effect or configuration.

As to suitable thermal carrying agents, many possible agents may be used. Liquid agents, having a greater mass than gaseous agents, are well suited for heat transport through a system. Water may be used provided that either the installation environment or regular use of the system prevents freezing. Aqueous solutions of sodium or calcium salts may also be used, which may provide a further degree of antifreeze protection. Likewise glycols may be added to a water agent, which may further expand the range of antifreeze and anti-boil protection in the system. Propylene glycol, being generally non-toxic, may be better used if leakage may occur from the system into the surrounding soil. Methyl or Ethyl alcohols may also be used, which may evaporate should these escape the system. Petroleum oils might also be economically used, and silicone oils might also be used, particularly at higher temperatures.

In the above disclosed systems, the thermal carrying agents are recirculated through the system, which may be a sealed system. A sealed system conserves the thermal agent and further inhibits calcium and other deposits on the walls of the various channels in the system. A sealed system may also be easier to maintain, while an unsealed system may require periodic topping-off. For a sealed system, a pressure relief valve may be incorporated in the system to prevent hydraulic pressure from building up and bursting system passages. An air pocket or expansion bladder may also be included offering similar protection.

In each of the exemplary systems above a fill cap is located at the highest point of the thermal agent circuit. Additionally, the tubing may be sloped throughout so as to avoid any pockets where air may accumulate, particularly in the TEG and dissipation conduit sections. By including these features, the system may be filled with a selected liquid agent while substantially purging any air from the system, preventing air pockets from occurring.

A non-sealed system might also utilize an automatic system to top off the coolant. In one example using water as the thermal carrying agent, the system is not sealed, but rather maintains an opening at the top of the circuit to the air. A float and valve are maintained at this opening to sense the level of the water in the system and cause water to enter the system at times of low levels.

Also in disclosed systems the included pump may be on only at times that a TEG is generating power. Optionally, the pump may be powered by the TEGs included, which might be done by simply utilizing a voltage regulator at a DC pump motor. Alternatively, the pump might be tied to a thermal sensor located on a collector plate or otherwise in proximity to a TEG, and powered from a battery or other external source.

A model has been developed to simulate a system as disclosed above, which will now be described.

When light passes through the Fresnel lens, some of the light is reflected back to the surrounding air, some is absorbed into the lens itself, and the remainder is transmitted through the lens to the absorber. The transmissivity of the lens, τ₂, is a property of the lens and its orientation. It is at maximum when the incident solar irradiation is normal to the lens' outer surface. The angle between the incident ray and the surface normal is called the angle of incidence. Solar tracking may be utilized to ensure that the collector is always oriented normal to the incident solar irradiation.

Solar power or flux is usually measured in watts per square meter, W/m². A typical solar flux under fair conditions in mid-latitudes is between 800 and 1000 W/m². Thus, if a solar flux of 900 W/m² were incident on a one square meter collector, 900 watts would be incident on that surface. When light is transmitted through a Fresnel lens, the flux is concentrated according to the formula:

$${G}_{s , new} = {G}_{s , old} ( \frac{{A}_{2}}{{A}_{1}} )$$

Where Gₛ is the solar flux transmitted through the lens, A₂ is the area of the lens and A₁ is the area of the surface on which the solar flux is focused. Obviously, as the area of the lens increases and the focused area decreases, the flux increases. The more the solar flux is concentrated, the more the temperature of the surface will increase.

Referring now to FIG. 5, in the model, the absorber plate 500 is made of high thermal conductivity aluminum. This allows the heat flux (q″_{H}) to be efficiently transferred to the TEG below it. The absorber plate is designed to maximize the heat absorbed. This is accomplished by painting the upper surface with a highly absorbing paint. The fraction of solar flux that is transferred to the absorber plate is determined by the transmissivity of the lens 502, the ratio of the area of the absorber plate to the area of the lens and the absorptance of the absorber plate, and is given by Gₛτ₂α₁A₂/A₁ using the symbol definitions in the table below:

| Symbol | Definition |
|---|---|
| T_{amb} | Ambient temperature |
| Gₛ | Solar flux incident on lens |
| τ₂ | Transmissivity of lens |
| α₁ | Absorbtivity of absorber plate |
| A₁ | Surface area of absorber plate |
| A₂ | Surface area of lens |
| q″_{H} | Heat flux leaving absorber plate |
| q″_{L} | Heat flux leaving TEG |
| W_{TEG} | Power generated by TEG |
| T₁ | Absorber Plate temperature |
| T₂ | Lens temperature |
| T₃ | Wall temperature |

In the model, the TEG is assumed to have a low thermal conductivity, which creates the large temperature drop across it. A low thermal conductivity also hinders the heat flow through the TEG. Heat, similar to a liquid, follows the path of least resistance. Thus, the enclosure may be insulated on the sides to minimize the amount of heat leakage through the sides. Maintaining the lower side of the TEG at the minimum possible temperature maximizes heat transfer through the TEG.

Again in the model, the coolant is circulated through the channel on the underside of the TEG using a pump. A large coolant tank, which is buried beneath the ground, serves to collect and cool the coolant after it flows through the coolant channel. The coolant is pumped from the coolant tank, through a main line, up to the collector coolant channels. From there it flows back down to the cooling tank. The collectors are placed in series, receiving coolant from the same header. The coolant is then collected and returned to the cooling tank.

Several elements of the system contribute to effective heat transfer. These elements are now discussed.

Coolant channel. The size of the coolant channel influences heat transfer from the bottom of the TEG. Smaller channels induce turbulent flow. Turbulent flow is much more effective in removing heat because of eddies that form within the channel. These eddies carry the heat away from the surface allowing more heat to be transferred to the coolant.

Mass flow rate. The mass flow rate refers to the rate at which the coolant flows through the channel. As the mass flow rate increases, the temperature difference across the TEG increases. A larger temperature difference results in a higher heat rate through the TEG and an increase in the power output.

Specific heat. The ability that a substance has to absorb heat is measured by its specific heat. The specific heat, C, is the amount of energy required to raise one kilogram of a substance by one degree Kelvin, and has units of kJ/kg•K. The coolant may advantageously have a high specific heat so that it can absorb a maximum amount of heat at a minimum flow rate. A coolant with a small specific heat would require a higher mass flow rate to absorb the same amount of heat. Although it is desirable to maintain a high enough mass flow rate to keep the TEG cool, the mass flow rate may be kept relatively low in order to minimize losses.

Losses. When coolant flows through the main line and channels, some friction is developed due to the viscosity of the liquid. This friction increases pumping power, and is referred to as head loss. Lowering the mass flow rate, choosing a smooth pipe, removing unnecessary bends and junctions, and increasing pipe diameter reduce head losses.

In the model TEG system, the pumping power is supplied by a fraction of the power output of the TEG. Thus, if the pump must work harder to overcome head losses, more of the TEG output power is consumed. To optimize the net power output from the TEG in the model, it is necessary to find a balance between the competing demands of maximizing the effectiveness of the heat transfer processes and minimizing the head losses.

Inherent in any model are assumptions, which serve to simplify mathematical calculations and enable the system to be modeled. The assumptions in this model are listed in the table below.

| Symbol | Assumption |
|---|---|
| q″_{conv} | No convection from the walls inside the enclosure |
| q″₃ | No net radiative heat flux from walls inside of the enclosure, |
| | q″₃ = 0 |
| R_{t,c} | Minimal contact resistance between TEG and absorber and |
| | channel |
| α_{1,2,3} | Enclosure surfaces are diffuse gray, α = ε |
| T_{1,2,3} | Enclosure surfaces are isothermal |

Several constants were selected for the model, which are representative of actual system parameters or operating environments. These constants are listed in the table below.

| Symbol | Description | Value | Units |
|---|---|---|---|
| width | Width of Fresnel lens | 50 | cm |
| t₂ | Thickness of absorber plate | 0.5 | cm |
| t_{TEG} | Thickness of TEG | 0.5 | cm |
| T_{amb} | Ambient air temperature | 298 | Kelvin |
| Gₛ | Solar Flux | 1000 | W/m² |
| k_{TEG} | Conductivity of TEG | 2.4 | W/m²K |
| h_{amb} | Convection coefficient of the ambient air | 6 | W/m²K |
| ε₁ | Emissivity of absorber | 1.0 | — |
| ε₂ | Emissivity of lens | 0.03 | — |
| ε₃ | Emissivity of walls | 1 | — |
| τ₃ | Transmissivity of lens | 0.9 | — |

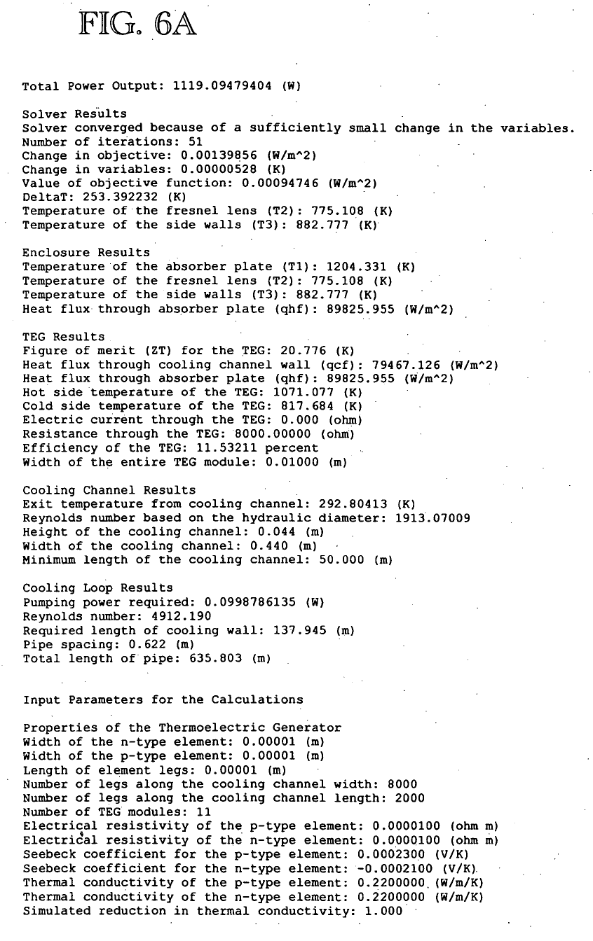

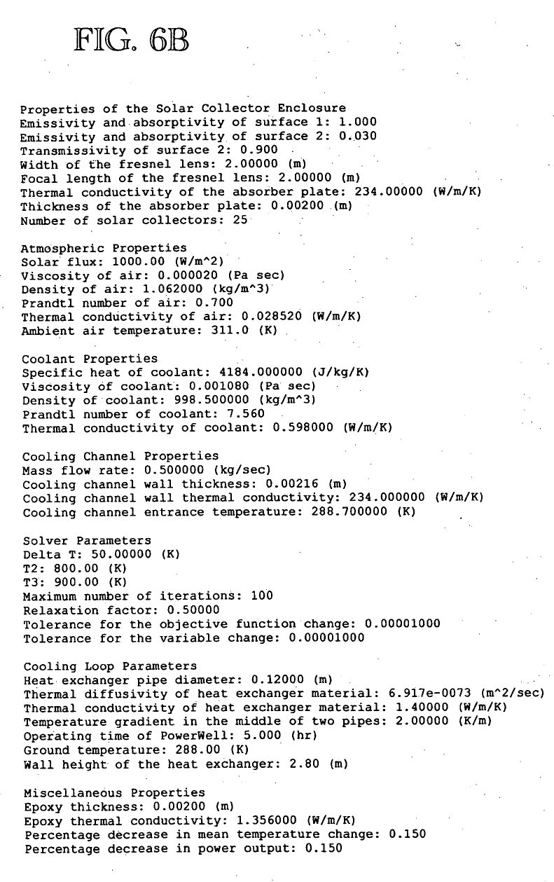

In the model, the most sensitive parameters to system efficiency are those relating to the TEG and the Fresnel lens, which are more specifically the TEG thickness, TEG conductivity, TEG Figure of Merit, Fresnel lens transmissivity and Fresnel lens width. A report of a model simulation utilizing water as a coolant appears in FIGS. 6A and 6B.

While thermoelectric generator systems dissipating into a foundational element have been described and illustrated in conjunction with a number of specific configurations and methods, those skilled in the art will appreciate that variations and modifications may be made without departing from the principles herein illustrated, described, and claimed. The present invention, as defined by the appended claims, may be embodied in other specific forms without departing from its spirit or essential characteristics. The configurations described herein are to be considered in all respects as only illustrative, and not restrictive. All changes which come within the meaning and range of equivalency of the claims are to be embraced within their scope.

1. A thermal transfer system for a set of thermoelectric generators, said set including at least one generator, each thermoelectric generator designed to produce electric power through the conduction of heat through the generator, comprising:
at least one TEG conduit suitable for channeling a thermal carrying liquid agent, said TEG conduit being configurable to be attached to at least one of the thermoelectric generators such that when attached heat may be transferred between the thermoelectric generators through said TEG conduit to liquid agent within said TEG conduit;
a building foundation portion, said foundation portion including a thermal mass;
a dissipation conduit embedded in said building foundation portion, said dissipation conduit including a channel through which the liquid agent may pass through, said dissipation conduit further including a transfer interface in substantial thermal communication with said foundation portion such that heat carried in the liquid agent may be transferred through said dissipation conduit to said building foundation portion when the liquid agent is hotter than the foundation portion;
connection conduits connecting said TEG conduits and said dissipation conduit, whereby said TEG conduits, said dissipation conduit and said connection conduits form a circuit for circulating the liquid agent through the system;
a pump configurable to circulate the liquid agent through said circuit at a specified rate;
wherein said building foundation portion has a shape and surface area sufficient to equalize the temperature of the thermal mass of said portion and surrounding matter at a sufficient rate such that the temperature of the foundation portion remains about the ambient temperature of the surrounding matter when said pump is circulating the liquid agent at the specified rate and the set of thermoelectric generators are conducting heat at a specified thermal rate and interval; and
wherein the transfer interface of said dissipation conduit has a shape, surface area and length sufficient to equalize the temperature between the liquid agent in the dissipation conduit and the building foundation portion at a sufficient rate such that the temperature of the liquid agent does not differ more than a specified amount when said pump is circulating the liquid agent at the specified rate and the set of thermoelectric generators are conducting heat at the specified thermal rate and interval.

2. The system of claim 1, wherein the dissipation conduit is buried entirely below a frost line.

3. The system of claim 1, wherein the dissipation conduit is buried entirely below a freezing line.

4. The system of claim 1, further comprising:
said set of thermoelectric generators; and
at least one solar radiation collector in thermal communication with said set of thermo-electric generators.

5. The system of claim 4, further comprising a cutout mechanism, whereby the solar input may be reduced if the temperature of a component of the system rises above a threshold.

6. The system of claim 4, wherein said building foundation portion, said dissipation conduit and said pump are configured to maintain a liquid agent of temperature of less than 120 degrees fahrenheit under conditions of full solar exposure.

7. The system of claim 4, further comprising a solar concentrator operable to concentrate solar radiation onto at least one of said solar radiation collectors under conditions of orientation with the sun.

8. The system of claim 1, wherein said building foundation portion comprises concrete.

9. A solar-electric generating device including a set of thermoelectric generators, said set including at least one generator, each thermo-electric generator designed to produce electric power through the conduction of heat through the generator at a specified thermal rate and interval, comprising:
at least one collector, each of said collectors absorbing solar radiation thereby generating heating of the collector;
for each of said collectors, at least one thermoelectric generator coupled to the collector to receive heat therefrom;
at least one heating conduit suitable for conducting a coolant liquid, said conduits being in thermal contact with said thermoelectric generators whereby heat may be transferred from the thermoelectric generators to a coolant liquid contained in the heating conduits;
a building foundation portion, said foundation portion including a thermal mass for accepting heat;
a cooling conduit embedded in said building foundation portion, said cooling conduit including a channel through which coolant liquid may pass through, said cooling conduit further including a transfer interface in substantial thermal communication with said foundation portion such that heat carried in the coolant liquid may be transferred through said cooling conduit to said building foundation portion;
connection conduits connecting said heating conduits and said cooling conduit, whereby said heating conduits, said cooling conduit and said connection conduits form a cooling circuit for circulating coolant liquid through the system;
a pump configurable to circulate the coolant liquid through said cooling circuit at a specified rate;
wherein said building foundation portion has a shape and surface area sufficient to dissipate heat into surrounding matter at a sufficient rate such that the temperature of the foundation portion remains about the ambient temperature of the surrounding matter; and
wherein the transfer interface of said cooling conduit has a shape, surface area and length sufficient to dissipate heat from coolant liquid in the cooling conduit into the building foundation portion at a sufficient rate such that the temperature of the coolant liquid does not rise above a specified temperature when said pump is circulating coolant liquid at the specified rate and the set of thermoelectric generators are conducting heat at the specified thermal rate and interval.

10. The system of claim 9, wherein the cooling conduit is buried entirely below a frost line.

11. The system of claim 9, wherein the cooling conduit is buried entirely below a freezing line.

12. The system of claim 9, further comprising a cutout mechanism, whereby the solar input may be reduced if the temperature of a component of the system rises above a threshold.

13. The system of claim 9, wherein said building foundation portion, said cooling conduit and said pump are configured to maintain a liquid agent of temperature of less than 120 degrees fahrenheit under conditions of full solar exposure.

14. The system of claim 9, further comprising a solar concentrator operable to concentrate solar radiation onto at least one of said solar radiation collectors under conditions of orientation with the sun.

15. A building including solar-electric generating device including a set of thermoelectric generators, comprising:
a foundation including a material comprising hydraulic cement;
optionally a structural framework supported on said foundation;
a roof supported on said foundation;
at least one collector, each of said collectors absorbing solar radiation thereby generating heating of the collector;
for each of said collectors, at least one thermo-electric generator coupled to the collector to receive heat therefrom;
at least one heating conduit suitable for conducting a coolant liquid, said conduits being in thermal contact with said thermo-electric generators whereby heat may be transferred from the thermoelectric generators to a coolant liquid contained in the heating conduits;
a cooling conduit embedded in said building foundation, said cooling conduit including a channel through which coolant liquid may pass through, said cooling conduit further including a transfer interface in substantial thermal communication with said foundation such that heat carried in the coolant liquid may be transferred through said cooling conduit to said building foundation;
connection conduits connecting said heating conduits and said cooling conduit, whereby said heating conduits, said cooling conduit and said connection conduits form a cooling circuit for circulating coolant liquid through the system;
a pump configurable to circulate the coolant liquid through said cooling circuit at a specified rate;
wherein said building foundation has a shape and surface area sufficient to dissipate heat into surrounding matter at a sufficient rate such that the temperature of the foundation portion remains about the ambient temperature of the surrounding matter; and
wherein the transfer interface of said cooling conduit has a shape, surface area and length sufficient to dissipate heat from coolant liquid in the cooling conduit into the building foundation at a sufficient rate such that the temperature of the coolant liquid does not rise above a specified temperature when said pump is circulating coolant liquid at the specified rate and the set of thermo-electric generators are conducting heat at the specified thermal rate and interval.

16. A system according to claim 15, wherein the foundation comprises concrete.

17. The system of claim 15, wherein the cooling conduit is buried entirely below a frost or a freezing line.

18. The system of claim 15, further comprising a cutout mechanism, whereby the solar input may be reduced if the temperature of a component of the system rises above a threshold.

19. The system of claim 15, wherein said building foundation portion, said cooling conduit and said pump are configured to maintain a liquid agent of temperature of less than 120 degrees Fahrenheit under conditions of full solar exposure.

20. The system of claim 15, further comprising a solar concentrator operable to concentrate solar radiation onto at least one of said solar radiation collectors under conditions of orientation with the sun.
